(19) United States
(12) Patent Application Publication
(10) Pub. No.: US 2012/0217953 A1
(43) Pub. Date: Aug. 30, 2012

(54) Methods for Sensing Cycle and Phase Difference of AC Signals

(75) Inventors: Feng Xiangguang, Wuxi (CN); Tao Jingjing, Wuxi (CN); Gu Qilong, Wuxi (CN)

(73) Assignee: RFdot Microelectronics Inc., Wuxi City (CN)

(21) Appl. No.: 13/407,514

(22) Filed: Feb. 28, 2012

(30) Foreign Application Priority Data
Feb. 28, 2011 (CN) 201110047298.8

(51) Int. Cl. G01R 25/00; G01R 19/00

(52) U.S. Cl. 324/86; 324/76.11

(57) ABSTRACT

The present disclosure discloses methods for sensing a cycle and a phase difference of an AC signal. A method for sensing the cycle of an AC signal may comprise the steps of: determining sample points in waveforms of the AC signal according to a fixed time interval; sampling N continuous sample points as one group of initial samples, in which the product of N and the fixed time interval is larger than or equal to the minimum cycle of the AC signal; sampling a plurality of groups of samples as a plurality of groups of target samples; calculating the cross-correlation between each group of the plurality of groups of target samples and the group of initial samples; and providing the time interval between the group of initial samples and a group of the target samples that has the highest cross-correlation as the cycle of the AC signal.

### CROSS-REFERENCE TO RELATED APPLICATIONS

This application claims the benefit of priority to China Patent Application with Application Number, 201110047298.8, filed on Feb. 28, 2011.

### FIELD OF THE PRESENT DISCLOSURE

At least one embodiment of the present invention pertains to the field of power transmission, and more particularly, to systems and methods for sensing a cycle and a phase difference of a multiple-phase AC (Alternating Current) signal.

### BACKGROUND

The phase of a three-phase AC signal can be obtained through three-phase synthetic vectors and coordinates transformation. But for an AC signal with only single-phase or lacking a phase, the phase cannot be calculated through the method.

For a single-phase AC signal, frequency is generally calculated according to a zero-crossing point in the AC signal, while the phase is estimated. The zero-crossing point indicates a point when the AC signal (a sine type signal) increases from a negative value to a positive value through X-Axis. As shown in FIG. 1, a rising-edge signal is sensed when the AC signal increases from a negative value to a positive value through a comparator and its related circuit. The time interval between two adjacent rising edges is a cycle T. The reciprocal of the cycle T is a frequency of the AC signal. If the time interval between a particular time and the previous zero-crossing point is t, the phase at this particular time can be expressed as t/T*360°.

However, the above-mentioned method has problems. The measurement accuracy and the sensing accuracy of the zero-crossing point are closely linked with each other. If a zero-crossing point is distorted by flutter near the zero-crossing point or at a relatively low sine degree, the rising-edge signal may be deviated from the actual zero-crossing point. If the zero-crossing point is not accurate, calculated cycle and phase of the AC signal are not accurate either.

In actual applications, not only the cycle and the phase difference of an AC signal are desired to be accurate, but also the measurement speed is required to be fast enough. An “instant” phase may be measured and processed. In addition, it is desired that more parameters of an AC signal can be measured, such as phase difference, phase sequence, or energy etc, between each phase of the AC signal. Obviously, the above-mentioned problems cannot be resolved with the existing solutions.

Therefore, the present inventors have recognized that there is value and need in providing methods for sensing the cycle and phase differences of an AC signal with high accuracy and fast speed.

### SUMMARY

The present disclosure may provide a method(s) for sensing the cycle of an AC signal with high measurement accuracy and fast measurement speed.

The present disclosure may also provide a method(s) for sensing a phase difference between different phase signals in an AC signal with high measurement accuracy and fast measurement speed.

According to one embodiment(s) of the present disclosure, a method for sensing a cycle of an AC signal may comprise the steps of: determining sample points, starting from a predetermined sample point, from waveforms of the AC signal according to a fixed time interval; sampling, starting from the predetermined sample point, N continuous sample points as one group of initial samples, in which N is an integral number, and the product of N and the fixed time interval is larger than or equal to the minimum cycle of the AC signal; sampling, starting from the predetermined sample point, a plurality of groups of samples and taking the plurality of groups of samples as a plurality of groups of target samples; calculating the cross-correlation between each group of the plurality of groups of target samples and the group of initial samples; and taking the time interval between the group of initial samples and a group of the target samples that has the highest cross-correlation as the cycle of the AC signal.

In some implementations, starting from a predetermined sample point may not include the predetermined sample point.

In some implementations, the group of initial samples may be indicated as B(n) and the plurality of groups of target samples may be indicated as B(n+k), in which n is an integer and n [1, N]; If k is the number of interval sample points between a group of target samples and the group of initial samples, the cross-correlation between the group of target samples and the group of initial samples may be calculated according to the following formula:

$${\sum }_{n = 1}^{N} B ( n ) * B ( n + k )$$

The product between the number of interval sample points k of a group of target samples, which has the highest cross-correlation, and the fixed time interval may be the cycle of the single-phase AC signal.

In some implementations, when a minimum cycle of a single-phase AC signal is sensed, the range of k may be between ((a minimum cycle estimated value minus a predetermined threshold value)/the fixed time interval, (the minimum cycle estimated value plus the predetermined threshold value)/the fixed time interval), in which (the minimum cycle estimated value plus the predetermined threshold value) is less than (2 times the minimum cycle estimated value).

According to another embodiment(s) of the present disclosure, a method for sensing a phase difference between different phase signals of a multiple-phase AC signal may comprise the steps of: determining sample points in waveforms of a first phase AC signal and a second phase AC signal, according to a fixed time interval; sampling, after a predetermined sample point, N continuous sample points from the first phase AC signal as one group of initial samples, wherein N is an integral number and the product of N and the fixed time interval is larger than or equal to the minimum cycle of said first phase AC signal; sampling, after the predetermined sample point, a plurality of groups of sample points from the second phase AC signal as a plurality of groups of target samples, in which each group of the plurality of groups of target samples comprises N continuous samples; calculating the cross-correlation between each group of the plurality of groups of target samples and the group of initial samples; calculating the time interval between the group of initial samples and a group of the target samples that has the highest cross-correlation; and calculating the phase difference between the first phase AC signal and the second phase AC signal according to the time interval between the group of initial samples and the group of the target samples that has the highest cross-correlation.

In some implementations, the group of initial samples may be indicated as A(n) and the plurality of groups of target samples may be indicated as B(n+k), in which nε[1, N]. If k is the number of interval sample points between a group of target samples and the group of initial samples, the cross-correlation between the group of target samples and the group of initial samples may be calculated according to the following formula:

$${\sum }_{n = 1}^{N} A ( n ) * B ( n + k )$$

In some implementations, k may be an integer and the range of k may be between [1, T/tc+M], in which T is the minimum cycle of a single-phase AC signal, tc is the fixed time interval, and M is an integer between 1 and 5.

In some implementations, the phase difference between the first-phase AC signal and the second-phase AC signal may be calculated according to the time interval between the group of initial samples and a group of target samples that has the highest cross-correlation. The method for calculating the phase difference may further comprises: calculating the time interval Tmax between the group of initial samples and a group of target samples that has the highest cross-correlation; and calculating the phase difference between the first-phase AC signal and the second-phase AC signal according to a formula: 360°*Tmax/T, in which T is the minimum cycle of the single-phase AC signal.

In some implementations, N may be equal to T/tc+S, in which T is the minimum cycle of the single-phase AC signal, tc is the fixed time interval, and S is an integer between 1 to 20.

In yet another embodiment(s) of the present disclosure, methods for sensing the cycle and the phase difference of an AC signal may be provided. A plurality of sample points from an AC signal may be sampled and taken as operands. The cycle and the phase difference may be calculated through calculations of the cross-correlation. Thus, the measurement accuracy of the cycle and the phase difference is high and may not be easily distorted by other factors, such as the distortion of the wave forms etc. In addition, the values of N and k may be adjusted to achieve fast and optimized calculation speed. Sample points obtained according to embodiment(s) the present disclosure may be used for calculating other parameters and further processing the AC signal.

### BRIEF DESCRIPTION OF THE DRAWINGS

One or more embodiments of the present invention are illustrated by way of example and not limitation in the figures of the accompanying drawings, in which like references indicate similar elements.

FIG. 1 illustrates a waveform schematic diagram for sensing a phase difference of a three-phase AC electrical signal.

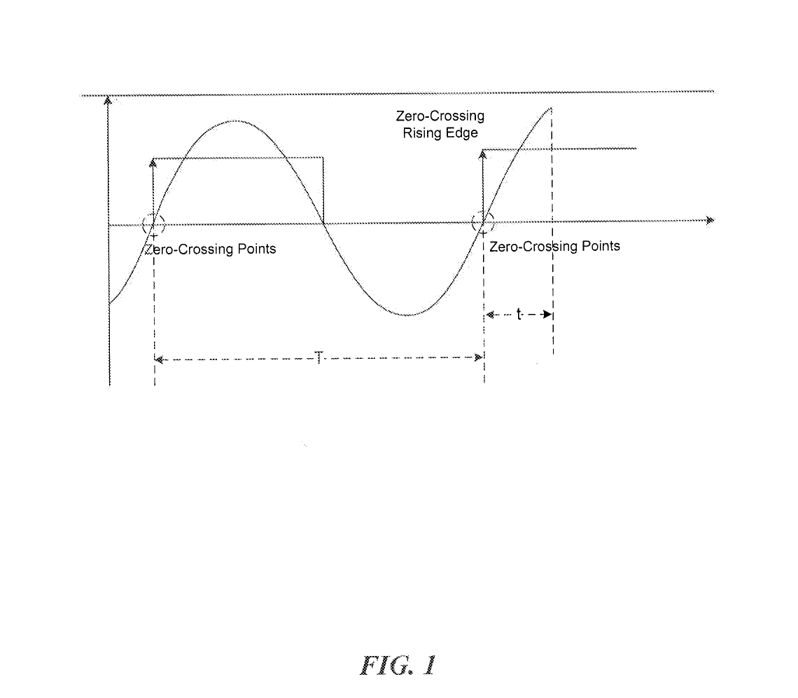

FIG. 2 illustrates a flow diagram for sensing the cycle of an AC signal according to one embodiment(s) of the present disclosure.

FIG. 3 illustrates a waveform schematic diagram of a single-phase AC signal according to another embodiment(s) of the present disclosure.

FIG. 4 illustrates a schematic diagram of a triangle transformation of a sinusoidal wave according to yet another embodiment(s) of the present disclosure.

FIG. 5 illustrates a flow diagram for sensing a phase difference between different phase signals of an AC signal according to yet another embodiment(s) of the present disclosure.

FIG. 6 illustrates a waveform schematic diagram of a first-phase AC signal and a second-phase AC signal according to yet another embodiments) of the present disclosure.

### DETAILED DESCRIPTION

References in this specification to “an embodiment”, “one embodiment”, or the like, mean that the particular feature, structure or characteristic being described is included in at least one embodiment of the present disclosure. Occurrences of such phrases in this specification do not necessarily all refer to the same embodiment.

The present disclosure provides a method for sensing a cycle of an AC signal.

Each phase signal of an AC signals may be in sine-type cyclic waveforms or cosine-type cyclic waveforms. Waveforms in each cycle may have the same characteristics. Target waveforms, which match waveforms of an initial cycle, may be found in waveforms of adjacent cycles. When the target waveforms are found, the cycle of the AC signal may also be found.

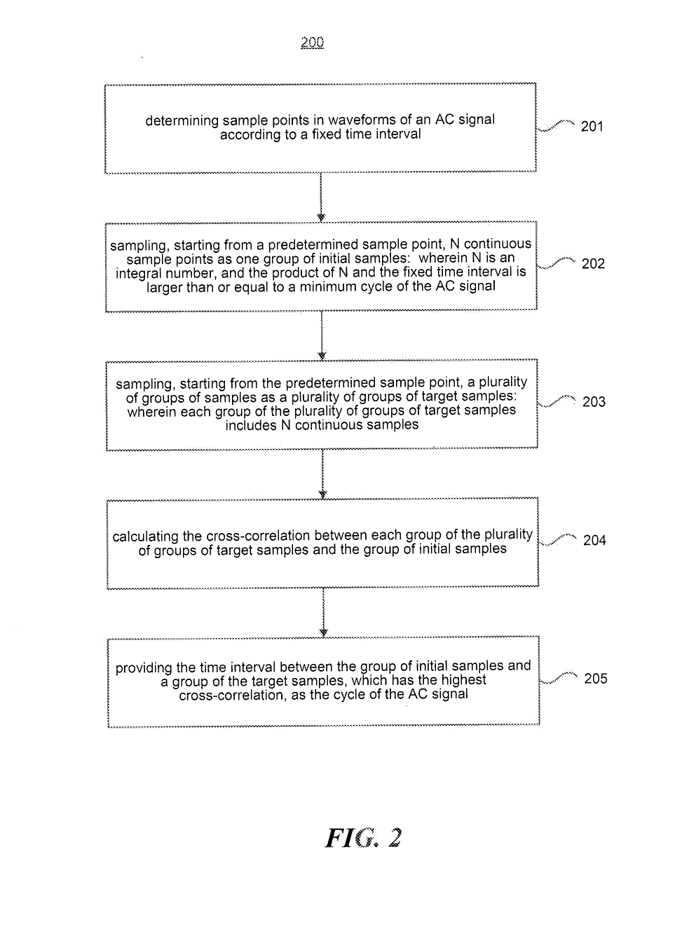

FIG. 2 illustrates a flow diagram for sensing the cycle of an AC signal according to one embodiment(s) of the present disclosure. Since each phase signal in a three-phase AC signal has the same cycle, only the cycle of one phase signal may be measured. In the following, a single phase AC signal and a single phase signal in a multiple-phase AC signal may all be called a single-phase AC signal. A method for sensing the cycle of a single-phase AC signal may comprise:

At step 201, sample points in waveforms of a signal-phase AC signal are determined according to a fixed time interval.

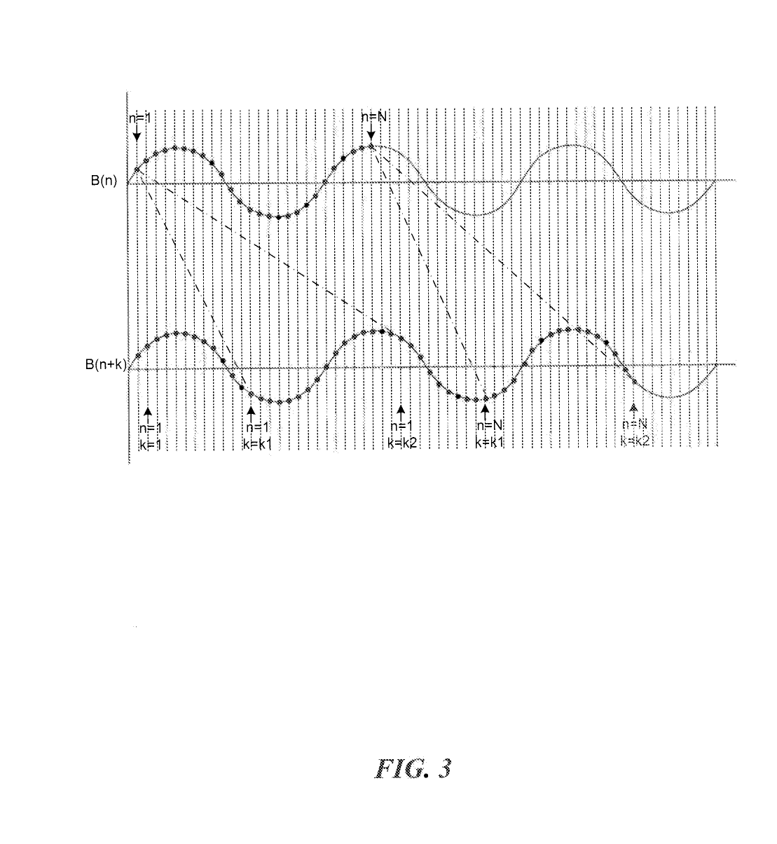

The single-phase AC signal may be sampled through a device, for example, an analog-to-digital converter. Waveforms may be sampled according to the fixed time interval. In some implementations, the fixed time interval may be a default fixed time interval of the analog-to-digital converter. Obviously, smaller the fixed time interval comparing with the cycle of the single-phase AC signal, higher accuracy calculated results may be achieved. In some implementations, a series of sample points may be obtained as illustrated in FIG. 3.

At step 202, N continuous sample points, after a predetermined sample point, may be sampled as one group of initial samples, in which N is an integral number, and the product of N and the fixed time interval is larger than or equal to the minimum cycle of the AC signal.

The predetermined sample point may be a sample point at any particular time. The predetermined sample point illustrated in FIG. 3 is a zero-crossing point, which is the point when the AC signal increases from a negative value to a positive value and passes through the X-axis. However, the predetermined sample point may be any sample point on waveforms. The zero-crossing point is only illustrated here as an example. Those skilled in the relevant art may easily understand that a sample point at any particular time may be taken as a predetermined sample point.

In some implementations, the group of initial samples may be indicated as B(n) and the plurality of groups of target samples may be indicated as B(n+k), in which n is an integer and nε[1, N]. Obviously, more sample points, higher accuracy calculations may be achieved. However, more sample points, more calculation resources and time may be required. In order to achieve high calculation accuracy while minimizing calculations needed, N continuous sample points may be sampled in a range covering at least the minimum cycle of the AC signal. In other words, the product of N and the fixed time interval may be larger than the minimum cycle of the AC signal.

In some implementations, about five-fourths of cycles of the waveforms are sampled and taken as the group of initial samples B(n), in which n is larger than and equal to 1, and is smaller and equal to N. In some implementations, N may be equal to 26.

In some implementations, the frequency of a three-phase AC signal may be known. Sample points covering slightly more than one cycle of a single-phase AC signal may be taken as the group of initial samples. In this way, not only the waveform characteristics may be preserved, but also the calculations needed may be reduced and optimized. In some implementations, the cycle of an AC signal is unknown. A large value may be selected for N as long as the value of N is slightly larger than the number of sample points in one cycle of the target signal.

At step 203, a plurality of groups of samples may be sampled after the predetermined sample point and taken as a plurality of groups of target samples. Each group of the plurality of groups of the sample points may be continuously sampled and comprise N continuous sample points.

In order to identify the waveforms in adjacent cycles that match the group of initial samples, a plurality of groups of the sample points may be continuously sampled after the predetermined sample point and taken as a plurality of groups of target samples in sequence. Each group of the target samples may comprise N continuous sample points. In some implementations, N continuous sample points may be sampled at k=k1 and taken as the first group of target samples, in which k is the number of the interval sample points between the group of target samples and the group of initial samples. Next, N continuous sample points may be sampled at k=k1+1 and taken as the second group of target samples. Next, N continuous sample points may be sampled at k=k1+2 and taken as the third group of target samples; N continuous sample points may be sampled at k=k2 and taken as the (k2−k1+1) group of target samples.

At step 204, cross-correlation between each group of the plurality of groups of target samples and the group of initial samples may be calculated.

The cross-correlation between each group of the plurality of groups of target samples and the group of initial samples may be calculated according to the following formula:

$${\sum }_{n = 1}^{N} B ( n ) * B ( n + k ) ; k ∈ ( k 1 , k 2 )$$

The cross-correlation may indicate the degree of similarity each group of the plurality of groups of target samples and the group of initial samples. The cross-correlation may reach a maximum value when the waveforms of a group of target samples and the group of initial samples are the same.

At step 205, the time interval between the group of initial samples and a group of the target samples that has the highest cross correlation may be provided as the cycle of the single-phase signal.

In some implementations, the product of the fixed time interval and k from the group of target samples that has the highest cross-correlation may be provided as the cycle of the single-phase AC signal.

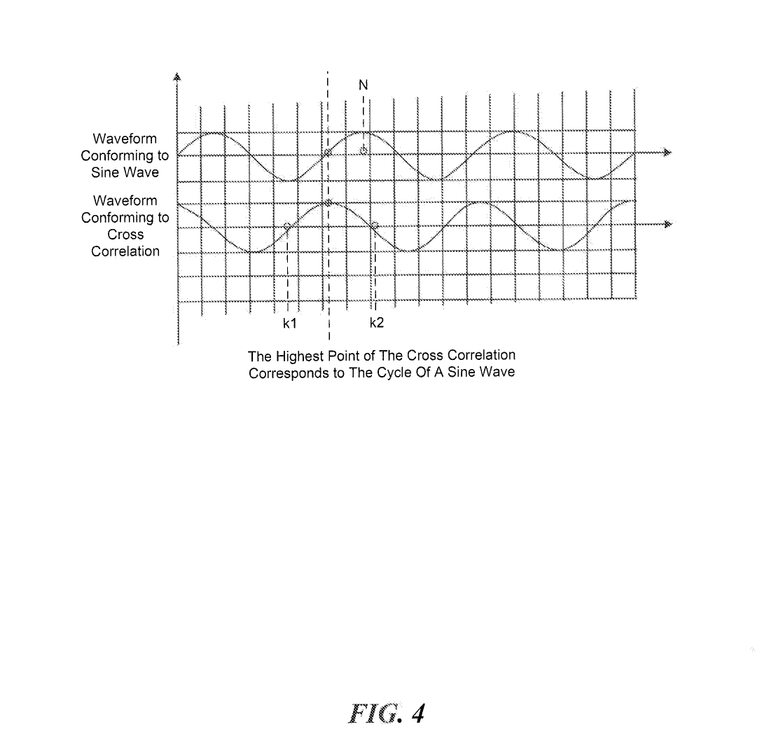

FIG. 4 illustrates a schematic diagram of a triangle transformation of a sinusoidal wave according to yet another embodiment(s) of the present disclosure. In some implementations, the waveforms of a single-phase AC signal may be in sin(x) type. The waveforms of a group of target samples may also be in sin(x) type. The cross-correlation of a group of target samples and the group of initial samples may have waveforms represented by sin(x1)*sin(x2). According to trigonometric functions transformation, sin α*sin β=−½[cos(α+β)−cos(α−β)]). Waveforms of the cross-correlation may be represented in cos(x) type.

In some implementations, when appropriate values are selected for (k1, k2), the maximum point in waveforms of the cross-correlation may correspond to the minimum cycle of the single-phase AC signal. In some implementations, when (k1, k2) have large values, the maximum point in waveforms of the cross-correlation may also correspond to the minimum cycle of the single-phase AC signal. In addition, there may be multiple maximum points in waveforms of the cross-correlation. In some implementations, in order to sense the minimum cycle of the single-phase AC signal, (k1, k2) may be selected in the range of ((a minimum cycle estimated value minus a predetermined threshold value)/the fixed time interval, (the minimum cycle estimated value plus the predetermined threshold value)/the fixed time interval), in which (the minimum cycle estimated value plus the predetermined threshold value) is less than (2 times the minimum estimated value).

In some implementations, the frequency of a three-phase AC signal may be known. For example, the cycle of a single-phase AC signal may cover between 19-21 sample points. To achieve fast calculations, N may be selected as 26, and (k1, k2) may be selected between (12, 28). In some implementations, N+k2=26+28=54 sample points may be sampled continuously. Then, 54 sample points may be divided into a group of initial samples and a plurality of groups of target samples.

According to yet another embodiment(s) of the present disclosure, a method for sensing the cycle of s single-phase AC signal may comprise: sampling a plurality of sample points in waveforms of the single-phase AC signal and taken the plurality of sample points as operands, and providing the cycle of the single-phase AC signal by calculating the cross-correlation. The cycle of the single-phase AC signal may be provided with high accuracy and the calculation results may not be easily distorted by other factors, such as the distortion of the wave forms etc. In addition, the values of N and k may be adjusted to achieve fast and optimized calculation speed. Sample points obtained according to embodiment(s) the present disclosure may be used for calculating other parameters and further processing the AC signal.

According to yet another embodiment(s) of the present disclosure, a method for sensing the phase difference of a three-phase AC signal may be provided. Cross-correlation may be used to identify waveforms in a second phase AC signal that match waveforms of initial samples in a first phase AC signal. The number of interval sample points between the waveforms in the second phase AC signal and the waveforms of initial samples in the first phase AC signal may be used to calculate the phase difference between the first phase AC signal and the second phase AC signal.

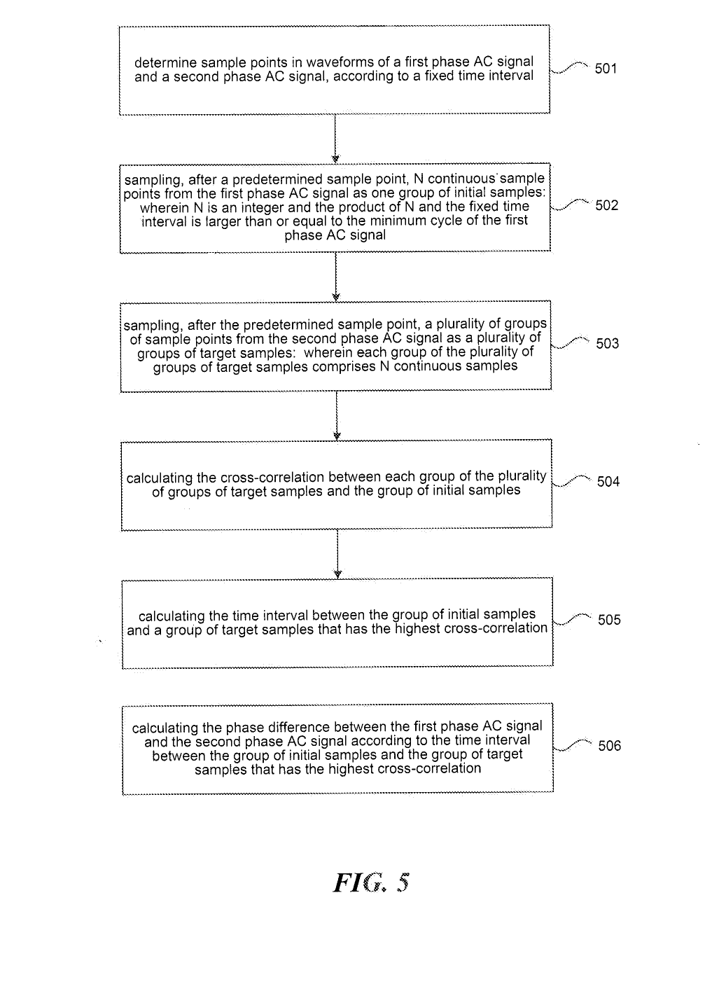

FIG. 5 illustrates a flow diagram for sensing a phase difference between different phase signals of an AC signal according to yet another embodiment(s) of the present disclosure. In some implementations, the flow diagram for sensing a phase difference between different phase signals of a multiple-phase signal may comprise the steps of:

At step 501, sample points in waveforms of a first phase AC signal and a second phase AC signal may be determined, according to a fixed time interval.

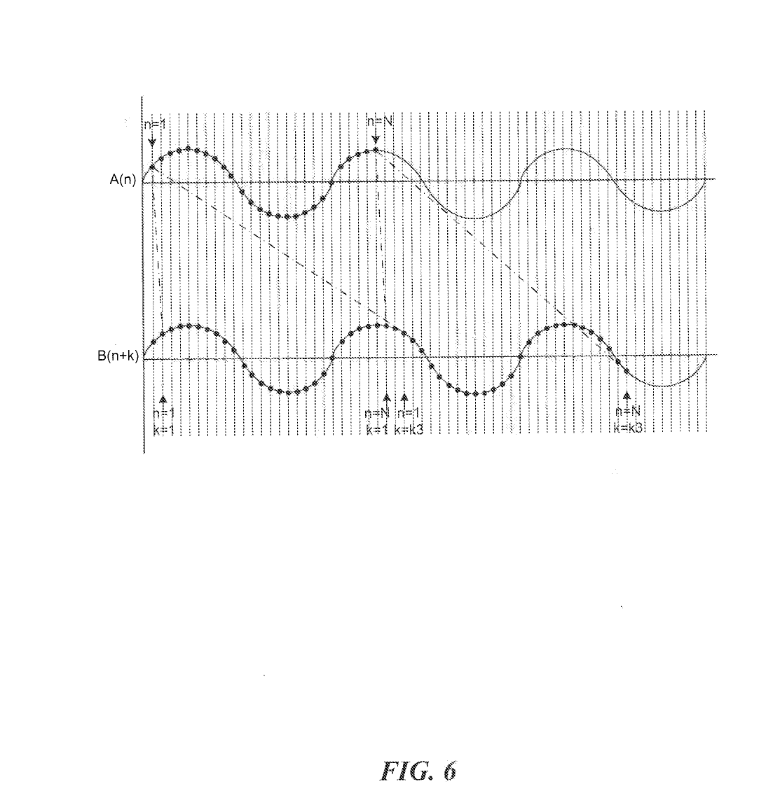

The single-phase signal of the AC signal may be sampled through a device, for example, an analog-to-digital converter. Waveforms may be sampled according to the fixed time interval. In some implementations, the fixed time interval may be a default fixed time interval of the analog-to-digital converter. Obviously, smaller the fixed time interval comparing with the cycle of the single-phase AC signal, higher accuracy calculated results may be achieved. In some implementations, a plurality of sample points in the first phase AC signal and the second phase AC signal may be obtained. The first phase AC signal may be sampled according to the upper half of FIG. 6 while the second phase AC signal may be sampled according to the lower half of FIG. 6.

At step 502, N continuous sample points, after a predetermined sample point, may be sampled from the first phase AC signal as one group of initial samples, in which N is an integral number and the product of N and the fixed time interval is larger than or equal to the minimum cycle of the first phase AC signal. The initial sample may be indicated as A(n), in which n is larger than or equal to N, and n is an integer.

The predetermined sample point may be a sample point at any particular time. The predetermined sample point illustrated in FIG. 6 is a zero-crossing point, which is the point when the AC signal increases from a negative value to a positive value and passes through the X-axis. However, the predetermined sample point may be any sample point on waveforms. The zero-crossing point is only illustrated here as an example. Those skilled in the relevant art may easily understand that a sample point at any particular time may be taken as a predetermined sample point.

In some implementations, N continuous sample points may be sampled, starting from the predetermined sample point of the first-phase AC signal, and taken as one group of initial samples B(n), in which n is larger than or equal to 1 and is less than or equal to N. Obviously, more sample points are sampled from the first phase AC signal, higher accuracy the calculations may be achieved. However, more sample points, more calculation resources and time may be required. In order to achieve high calculation accuracy while minimizing calculations needed, N continuous sample points may be sampled in a range covering at least the minimum cycle of the first phase AC signal. In other words, the product of N and the fixed time interval may be larger than the minimum cycle of the first phase AC signal.

In some implementations, about five-fourths of cycles of the waveforms are sampled and taken as the group of initial samples B(n), in which n is larger than and equal to 1, and is smaller and equal to N. In some implementations, N may be equal to 26. In some implementations, sample points covering slightly more than one cycle of the single-phase AC signal may be taken as the group of initial samples. In this way, not only the waveform characteristics may be preserved, but also the calculations needed may be reduced and optimized.

At step 503, a plurality of groups of sample points, after the predetermined sample point, may be sampled from the second phase AC signal and taken as a plurality of groups of target samples according to the fixed time interval. Each group of the plurality of groups of target samples may comprise N continuous samples. A group of target sample may be indicated as B(n+k), in which k is the number of interval sample points between a group of target samples and the group of initial samples and k is an integer.

In order to identify waveforms in the second phase AC signal that match the group of initial samples in the first phase AC signal, a plurality of groups of sample points, after the predetermined sample point of the first phase AC signal, may be sampled from the second phase AC signal and taken as a plurality of groups of target samples. Each group of target samples may comprise N continuous samples. In some implementations, N continuous sample points may be sampled at k=1 and taken as the first group of target samples. Next, N continuous sample points may be sampled at k=2 and taken as the second group of target samples . . . N continuous sample points may be sampled at k=k3 and taken as the (k3−k1+1) group of target samples. In some implementations, the range of K3 may be more than or equal to the length of one cycle, in which K3 may be equal to 28.

At step 504, the cross-correlation between each group of the plurality of groups of target samples and the group of initial samples may be calculated. In some implementations, the cross correlation may be calculated according to the following formula:

$${\sum }_{n = 1}^{N} A ( n ) * B ( n + k )$$

The group of target samples with the highest cross-correlation value may represent waveforms in the second phase AC signal that match the waveforms of initial samples in the first-phase AC signal. When the group of target samples with the highest cross-correlation is identified, its k value may represent the number of sample points in the phase difference between the first-phase electrical signal and the second-phase electrical signal. In order to provide the phase difference in degree, a conversion may be needed.

At step 505, the time interval between said group of initial samples and a group of the target samples that has the highest cross correlation may be calculated according to the product the fixed time interval and the number of interval sample points between the group of target samples and the group of initial samples.

The time interval Tmax between the group of initial samples and the group of target samples that has the highest cross-correlation may be calculated according to the following formula: Tmax=k*tc.

At step 506, the phase difference between the first phase AC signal and the second phase AC signal may be calculated according to the time interval between the group of initial samples and the group of the target samples that has the highest cross correlation.

In some implementations, the phase difference between the first phase AC signal and the second AC signal may be calculated according to formula of 360°*Tmax/T, wherein T is the minimum cycle of a single-phase AC signal.

Obviously, the minimum cycle of the first-phase electrical signal and the second-phase electrical signal may be obtained through the method(s) for sensing the cycle of an AC signal, as illustrated in FIG. 2.

In some implementations, the cycle of a three-phase AC signal may be known. In order to achieve high accuracy in calculations while minimizing calculations required, N may be set as N=T/tc+S, in which T is the minimum cycle of a single-phase AC signal in the three-phase AC signal, tc is the fixed time interval, and M is an integer between 1 and 20. While specific embodiments, and examples for the disclosure, are described above for illustrative purpose, a phase difference between a second-phase signal and a third-phase signal of a three-phase AC or a phase difference any two phase signals in a multiple-phase AC signal may be calculated according the embodiments of the present disclosure, as those skilled in the relevant art will recognize.

According to yet another embodiment(s) of the present disclosure, the number of interval sample points k may be used in a method for sensing the cycle of an AC signal. The number of interval sample points may be used to identify waveforms of a group of target samples in adjacent cycles that match waveforms of a group of initial samples. The group of target samples may be located in the neighborhood of next cycle. The range of k may be centered around a minimum cycle estimated value and in the range of plus/minus a predetermined threshold value. According to yet another embodiment(s) of the present disclosure, the number of interval sample points may be used in a method for sensing the phase difference between a first phase AC signal and a second phase AC signal. The number of sample intervals k may be used to identify waveforms of a group of target samples in the second phase AC signal that match waveforms of a group of initial samples in the first phase AC signal. The group of target sample may be located in a range, starting from the predetermined sample point of the first phase AC signal, with a length equal to or larger than a cycle of a single-phase AC signal. In some implementations, the range of k may be set as [1, T/tc+M], wherein T is the minimum cycle of the single-phase AC signal, tc is the fixed time interval, and M is an integer between 1 and 5.

In yet another embodiment(s) of the present disclosure, methods for sensing the phase difference of a three-phase AC signal may be provided. A plurality of group of sample points from different phase AC signals may be sampled and taken as operands. The phase difference may be calculated through calculations of the cross-correlation. Thus, the measurement accuracy of the phase difference is high, and may not be easily distorted by other factors, such as the distortion of the wave forms etc. In addition, the values of N and k may be adjusted to achieve fast and optimized calculation speed. Sample points obtained according to embodiment(s) the present disclosure may be used for calculating other parameters and further processing the AC signal.

The above description has fully disclosed the embodiments of the present disclosure. It is needed to point out that any alteration of the embodiments of the present disclosure made by those skilled in the prior art shall not be departed from the scope of the claims of the present disclosure. Correspondingly, the scope of the claims of the present disclosure is not also limited to the embodiments.

The foregoing description has been presented with reference to specific embodiments for purposes of illustration and explanation. However, the illustrative discussions above are not intended to be exhaustive or to limit the present disclosure to the embodiments described. A person skilled in the art may appreciate that many modifications and variations are possible in view of the present disclosure.

What is claimed is:

1. A method for sensing a cycle of an AC signal, comprising:
determining sample points in waveforms of the AC signal according to a fixed time interval;
sampling, starting from a predetermined sample point, N continuous sample points as one group of initial samples; wherein N is an integral number, and the product of N and said fixed time interval is larger than or equal to a minimum cycle of said AC signal;
sampling, starting from said predetermined sample point, a plurality of groups of samples as a plurality of groups of target samples; wherein each group of said plurality of groups of target samples includes N continuous samples;
calculating the cross-correlation between each group of said plurality of groups of target samples and said group of initial samples; and
providing the time interval between said group of initial samples and a group of the target samples, which has the highest cross-correlation, as said cycle of said AC signal.

2. A method as recited in claim 1, wherein said starting from a predetermined sample point does not include said predetermined sample point.

3. A method as recited in claim 1, wherein said group of initial samples is set as B(n) and said plurality of groups of target samples is set as B(n+k); wherein n is an integer and nε[1, N]; if k is the number of interval sample points between a group of target samples and said group of initial samples, the cross-correlation between said group of target samples and said group of initial samples is calculated according to the following formula:
$${\sum }_{n = 1}^{N} B ( n ) * B ( n + k )$$

4. A method as recited in claim 3, wherein, when the minimum cycle of said AC signal is sensed, the range of k is between ((a minimum cycle estimated value minus a predetermined threshold value)/said fixed time interval, (said minimum cycle estimated value plus said predetermined threshold value)/said fixed time interval); wherein (said minimum cycle estimated value plus said predetermined threshold value) is less than (2 times said minimum cycle estimated value).

5. A method for sensing a phase difference between different phase signals of a multiple-phase AC signal, comprising:
determining sample points in waveforms of a first phase AC signal and a second phase AC signal, according to a fixed time interval;
sampling, after a predetermined sample point, N continuous sample points from said first phase AC signal as one group of initial samples; wherein N is an integer and the product of N and said fixed time interval is larger than or equal to the minimum cycle of said first phase AC signal;
sampling, after said predetermined sample point, a plurality of groups of sample points from said second phase AC signal as a plurality of groups of target samples; wherein each group of said plurality of groups of target samples comprises N continuous samples;
calculating the cross-correlation between each group of said plurality of groups of target samples and said group of initial samples;
calculating the time interval between said group of initial samples and a group of target samples that has the highest cross-correlation; and
calculating the phase difference between said first phase AC signal and said second phase AC signal according to said time interval between said group of initial samples and said group of target samples that has the highest cross-correlation.

6. A method as recited in claim 5, wherein said group of initial samples is set as A(n) and said plurality of groups of target samples is set as B(n+k); wherein nε[1, N]; if k is the number of interval sample points between a group of target samples and said group of initial samples, the cross-correlation between said group of target samples and said group of initial samples is calculated according to the following formula:
$${\sum }_{n = 1}^{N} A ( n ) * B ( n + k )$$

7. A method as recited in claim 6, wherein k is an integer and has a range of [1, T/tc+M]; wherein T is the minimum cycle of a single-phase signal in said multiple-phase AC signal, tc is said fixed time interval, and M is an integer between 1 and 5.

8. A method as recited in claim 7, wherein, when the minimum cycle of said single-phase signal in said multiple-phase AC signal is sensed, the range of k is between ((a minimum cycle estimated value minus a predetermined threshold value)/said fixed time interval, (said minimum cycle estimated value plus said predetermined threshold value)/said fixed time interval); wherein (said minimum cycle estimated value plus said predetermined threshold value) is less than (2 times said minimum cycle estimated value).

9. A method as recited in claim 6, further comprising: calculating the time interval Tmax, between said group of initial sample and a group of target samples that has the highest cross-correlation, according to the product of said fixed time interval and the number of interval sample points between said group of target samples and said group of initial samples; and calculating said phase difference between said first-phase AC signal and said second-phase AC signal according to a formula: 360°*Tmax/T; wherein T is the minimum cycle of said single-phase signal in said multiple-phase AC signal.

10. A method as recited in claim 9, wherein, when the minimum cycle of a single-phase signal in said multiple-phase AC signal is sensed, the range of k is between ((a minimum cycle estimated value minus a predetermined threshold value)/said fixed time interval, (a minimum cycle estimated value plus a predetermined threshold value)/said fixed time interval); wherein (said minimum cycle estimated value plus said predetermined threshold value) is less than (2 times said minimum cycle estimated value).

11. A method as recited in claim 6, wherein N is equal to T/tc+S; wherein T is the minimum cycle of a single-phase signal in said multiple-phase AC signal, tc is said fixed interval, and S is an integer between 1 to 20.

12. A method as recited in claim 11, wherein, when the minimum cycle of said single-phase signal in said multiple-phase AC signal is sensed, the range of k is between ((a minimum cycle estimated value minus a predetermined threshold value)/said fixed time interval, (a minimum cycle estimated value plus a predetermined threshold value)/said fixed time interval); wherein (said minimum cycle estimated value plus said predetermined threshold value) is less than (2 times said minimum cycle estimated value).
